(19) United States
(12) Patent Application Publication
(10) Pub. No.: US 2024/0235147 A1
(43) Pub. Date: Jul. 11, 2024

(54) POTASSIUM DIHYDROGEN PHOSPHATE (KDP) FREQUENCY-DOUBLING CRYSTAL STRUCTURE

(71) Applicant: Tianshui Normal University, Tianshui City (CN)

(72) Inventors: Weijun LING, Tianshui City (CN); Jinfang YANG, Tianshui City (CN); Mingxia ZHANG, Tianshui City (CN); Yongle ZHU, Tianshui City (CN); Yuping WANG, Tianshui City (CN); Feiping LU, Tianshui City (CN); Xiangbing LI, Tianshui City (CN); Limin ZHAO, Tianshui City (CN); Yuxiang ZHAO, Tianshui City (CN); Lijun ZHANG, Tianshui City (CN); Zhong DONG, Tianshui City (CN)

(21) Appl. No.: 18/395,975

(22) Filed: Dec. 26, 2023

(30) Foreign Application Priority Data
Jan. 6, 2023 (CN) 202310022044.3

(51) Int. Cl. H01S 3/109; C30B 29/14; G02F 1/37; H01S 3/08

(52) U.S. Cl. CPC H01S 3/109; C30B 29/14; G02F 1/37; H01S 3/08054

(57) ABSTRACT

The present disclosure provides a potassium dihydrogen phosphate (KDP) frequency-doubling crystal structure, including a crystal fixing structure, a KDP crystal, a π polarization tube, and a σ polarization tube; where a π-polarized laser with a central wavelength of 800 nm enters the KDP crystal through the π polarization tube, and the KDP crystal converts the π-polarized laser with a central wavelength of 800 nm into a σ-polarized laser with a central wavelength of 400 nm by frequency doubling and then outputs the σ-polarized laser from the σ polarization tube. Close end bevels of the π polarization tube and the σ polarization tube are designed into a Brewster angle. The KDP crystal is placed in a vacuum-sealed cavity formed by the π polarization tube, the σ polarization tube, and the crystal fixing structure, which eliminates a complicated process of crystal coating and prevents the KDP crystal from deliquescing in air.

### CROSS REFERENCE TO RELATED APPLICATION

This patent application claims the benefit and priority of Chinese Patent Application No. 202310022044.3, filed with the China National Intellectual Property Administration on Jan. 6, 2023, the disclosure of which is incorporated by reference herein in its entirety as part of the present application.

### TECHNICAL FIELD

The present disclosure relates to the technical field of lasers, and in particular to a potassium dihydrogen phosphate (KDP) frequency-doubling crystal structure.

### BACKGROUND

Chirped pulse amplification (CPA), for generating ultra-intense and ultra-short laser pulses, is currently one of the most innovative amplification technologies with development potential. Combined with the discovery of high-performance gain media, the laser peak power that can be achieved on ordinary optical platforms has been improved by 7 orders of magnitude in just a few years through the CPA and now reaches a magnitude of 10 petawatt (PW, 1 PW=10¹⁵ W). The CPA system using Nd:glass as an amplification medium has achieved a pulse output of 1.5 PW with a central wavelength of 1,064 nm; the CPA system using Ti:sapphire-doped titanium sapphire crystal as an amplification medium has currently achieved 10 PW and becomes a mainstream development direction of the current CPA amplification system. The central wavelength of the amplification system is 800 nm. The pulse with a peak power at the magnitude of terawatt (TW, 1 TW=10¹² W) and a pulse width at the magnitude of femtosecond (fs, 1 fs=10⁻¹⁵ s) can generate a laser intensity exceeding 10²⁰ W/cm². This ultra-intense pulse exhibits wide applications in high-order harmonic emission, ultra-high-density plasma acquisition, ultra-fast X-ray generation, inertial confinement nuclear fusion, and miniaturized high-gradient particle accelerators, providing a powerful means to obtain these extreme conditions.

However, such an ultra-intense pulse has output bands generally in the infrared and near-infrared, which need to be extended frequencies to the visible and even ultraviolet bands. Currently, wavelength down-conversion is most commonly achieved through a type of phase-matched frequency doubling method. This ultrashort pulse after frequency-doubling can effectively reduce background noise and pre-pulse amplitude, and is conducive to a clearer understanding of the physical essence of interactions between the main pulse and matter. Due to a low group velocity mismatch coefficient (83 fs/mm), a large acceptance angle (4 min/cm), and a reception bandwidth (1.6 nm/cm) much larger than that of beta-barium borate (BBO) and lithium triborate (LBO) crystals, the potassium dihydrogen phosphate (KDP) crystal has become the frequency-doubling crystal of choice for broadband high-intensity pulses. During the frequency-doubling of ultrashort pulses, there is a serious group velocity mismatch between the fundamental wave and the frequency-doubling wave, which greatly limits a length of the frequency-doubling crystal to generally 1 mm to 2 mm. In order to obtain a high conversion efficiency for such a short crystal, an intensity of the fundamental frequency light must be increased to generally greater than (100 GW/cm²). Such a strong fundamental frequency light can easily cause damages to the coating layer, thereby affecting a service life of the KDP crystal, and then placing higher requirements on coating of the crystal. Moreover, thin KDP is easily deliquescent in the air and must be placed in a vacuum closed box to conduct coating with a sol, thereby further increasing the difficulty of crystal coating.

In view of this, it is necessary to propose a new crystal design solution to address the shortcomings of the current crystal KDP coating layer, which is susceptible to damages caused by high-intensity fundamental frequency light, resulting in short service life, increased coating difficulty, and increased coating technology requirements on the crystal.

### SUMMARY

An objective of the present disclosure is to provide a KDP frequency-doubling crystal structure. In the present disclosure, since there is theoretically no loss when a linearly-polarized light is incident in a P plane at the Brewster angle, a π polarization tube and a σ polarization tube are designed to vacuumize and seal an incident plane and an emitting plane of the KDP crystal, respectively. This process replaces the existing crystal coating and overcomes vulnerability of the existing KDP crystal coating layer to damages caused by high-intensity fundamental frequency light, thus avoiding the short service life, increased coating difficulty, and increased coating technical requirements on the crystal.

To achieve the above objective, the present disclosure provides the following technical solutions:

The present disclosure provides a KDP frequency-doubling crystal structure, including:
a crystal fixing structure;
a KDP crystal, where the KDP crystal is fixed on the crystal fixing structure, and an incident plane and an emitting plane of the KDP crystal are exposed outside two sides of the crystal fixing structure, respectively; and the KDP crystal is configured to convert a π-polarized laser with a central wavelength of 800 nm into a σ-polarized laser with a central wavelength of 400 nm by frequency doubling;
a π polarization tube, where the π polarization tube has one open end and the other end closed by a Brewster angle bevel; a vacuumizing port is provided on a wall of the π polarization tube; the open end of the π polarization tube is sealingly connected to one side of the crystal fixing structure to seal the incident plane of the KDP crystal; and the π polarization tube is configured to allow high transmission of the π-polarized laser with a central wavelength of 800 nm;
a σ polarization tube, where the σ polarization tube has one open end and the other end closed by a Brewster angle bevel; a vacuumizing port is provided on a wall of the σ polarization tube; the open end of the σ polarization tube is sealingly connected to the other side of the crystal fixing structure to seal the emitting plane of the KDP crystal; and the Brewster angle bevel of the σ polarization tube and the Brewster angle bevel of the π polarization tube are perpendicular to each other, and the σ polarization tube is configured to allow high transmission of the σ-polarized laser σ with a central wavelength of 400 nm;
a hollow clamp, where a cylindrical mounting hole is provided at a center of the hollow clamp; one axial end of the cylindrical mounting hole is provided with a closing ring to prevent the KDP crystal from falling off; the cylindrical crystal is arranged in the cylindrical mounting hole, and one axial end of the cylindrical crystal is abutted against the closing ring; and an inner ring of the closing ring is configured to expose one of the incident plane and the emitting plane; and
a fixing member, where the fixing member is connected to the other end of the cylindrical mounting hole and abuts against the other axial end of the cylindrical crystal to fix the cylindrical crystal inside the cylindrical mounting hole; and a hollow-out hole is provided at a center of the fixing member to expose the other one of the incident plane and the emitting plane.

Optionally, the hollow clamp is a cylindrical hollow clamp, and the cylindrical mounting hole is coaxially arranged with the cylindrical hollow clamp; a middle part of the cylindrical hollow clamp protrudes radially outward to form a stepped ring; the open end of the π polarization tube is sleeved on one end of the cylindrical hollow clamp and is sealingly connected to one end face of the stepped ring; and the open end of the σ polarization tube is sleeved on the other end of the cylindrical hollow clamp and is sealingly connected to the other end face of the stepped ring.

Optionally, the open end of the π polarization tube is bonded and sealed with one end face of the stepped ring; and the open end of the σ polarization tube is bonded and sealed with the other end face of the stepped ring.

Optionally, a plurality of through holes parallel to an axial direction of the cylindrical hollow clamp are provided in a side wall of the cylindrical hollow clamp, the plurality of through holes are evenly distributed along a circumferential direction of the cylindrical hollow clamp, and both ends of each of the through holes penetrate two axial ends of the cylindrical hollow clamp to communicate with the π polarization tube and the σ polarization tube.

Optionally, the fixing member is threadedly connected to the cylindrical mounting hole.

Optionally, the π polarization tube and the σ polarization tube each are a cylindrical polarization tube, and the cylindrical crystal, the π polarization tube, and the σ polarization tube are arranged coaxially.

Optionally, the π polarization tube and the σ polarization tube each are a quartz glass tube; and the Brewster angle bevel of the π polarization tube and an axis of the π polarization tube form an included angle of 34.5°, while the Brewster angle bevel of the σ polarization tube and an axis of the σ polarization tube form an included angle of 34.2°.

Optionally, the cylindrical crystal has a type-I phase matching angle of 43° 42′, a cross-sectional diameter of 7 mm, and an axial length of 2 mm.

Optionally, the crystal fixing structure is prepared from polytetrafluoroethylene (PTFE).

Compared with the prior art, the present disclosure has the following technical effects:

The present disclosure proposes a high-power KDP frequency-doubling crystal structure; where a π-polarized laser with a central wavelength of 800 nm enters the KDP crystal through the π polarization tube, and the KDP crystal converts the π-polarized laser with a central wavelength of 800 nm into a σ-polarized laser with a central wavelength of 400 nm by frequency doubling and then outputs the σ-polarized laser from the σ polarization tube. Close end bevels of the π polarization tube and the σ polarization tube are designed into a Brewster angle. The KDP crystal is placed in a vacuum-sealed cavity formed by the π polarization tube, the σ polarization tube, and the crystal fixing structure, which eliminates a complicated process of crystal coating and prevents the KDP crystal from deliquescing in air. This process overcomes the problem that a KDP coating layer of existing crystals is susceptible to damage by high-intensity fundamental frequency light, thereby avoiding a short service life, an increased difficulty of coating, and an increased technical requirement for coating of the crystal. The components in the entire crystal structure, such as the π polarization tube, σ polarization tube, and crystal fixing structure, have a simple configuration that can be obtained through simple mechanical processing with a low manufacturing cost.

In the present disclosure, the KDP frequency-doubling crystal structure can be used efficiently for a long time, providing a feasible new technical way to obtain the KDP crystal with a high damage threshold under high-power frequency-doubling, and shows a strong practicability.

### BRIEF DESCRIPTION OF THE DRAWINGS

To describe the technical solutions in embodiments of the present disclosure or in the prior art more clearly, the accompanying drawings required for the embodiments are briefly described below. Apparently, the accompanying drawings in the following description show merely some embodiments of the present disclosure, and those of ordinary skill in the art may still derive other accompanying drawings from these accompanying drawings without creative efforts.

FIG. 1 shows a schematic diagram of a breakdown structure of the KDP frequency-doubling crystal structure disclosed in an example of the present disclosure;

FIG. 2 shows a schematic diagram of an overall structure of the KDP frequency-doubling crystal structure disclosed in an example of the present disclosure;

FIG. 3 shows a ray tracing diagram simulated using TracePro software disclosed in an example of the present disclosure;

FIG. 4 shows a schematic diagram of the π-polarized laser incident on the π polarization tube simulated using TracePro software disclosed in an example of the present disclosure;

FIG. 5 shows a polarization analysis diagram of an emitted laser of the π-polarized laser passing through the π polarization tube disclosed in an example of the present disclosure;

FIG. 6 shows a schematic diagram of the σ-polarized laser incident on the σ polarization tube simulated using TracePro software disclosed in an example of the present disclosure; and

FIG. 7 shows a polarization analysis diagram of an emitted laser of the σ-polarized laser passing through the σ polarization tube disclosed in an example of the present disclosure.

Reference numerals in the accompanying drawings are as follows:
100. KDP frequency-doubling crystal structure;
1. Crystal fixing structure; 11. Hollow clamp; 12. Cylindrical mounting hole; 13. Fixing member; 14. Hollow-out hole; 15. Stepped ring; 16. Through hole; 17. Closing ring; 2. KDP crystal; 3. π polarization tube; 4. Brewster angle bevel; 5. Vacuumizing port; 6. σ polarization tube.

### DETAILED DESCRIPTION OF THE EMBODIMENTS

The technical solutions of the embodiments of the present disclosure are clearly and completely described below with reference to the drawings in the embodiments of the present disclosure. Apparently, the described embodiments are merely a part rather than all of the embodiments of the present disclosure. All other embodiments obtained by those skilled in the art based on the embodiments of the present disclosure without creative efforts shall fall within the protection scope of the present disclosure.

An objective of the present disclosure is to provide a KDP frequency-doubling crystal structure. In the present disclosure, since there is theoretically no loss when a linearly-polarized light is incident in a π plane at the Brewster angle, a π polarization tube and a σ polarization tube are designed to vacuumize and seal an incident plane and an emitting plane of the KDP crystal, respectively. This process replaces the existing crystal coating and overcomes vulnerability of the existing KDP crystal coating layer to damages caused by high-intensity fundamental frequency light, thus avoiding the short service life, increased coating difficulty, and increased coating technical requirements on the crystal.

In order to make the above objective, features and advantages of the present disclosure clearer and more comprehensible, the present disclosure will be further described in detail below in combination with accompanying drawings and particular implementation modes.

### Example 1

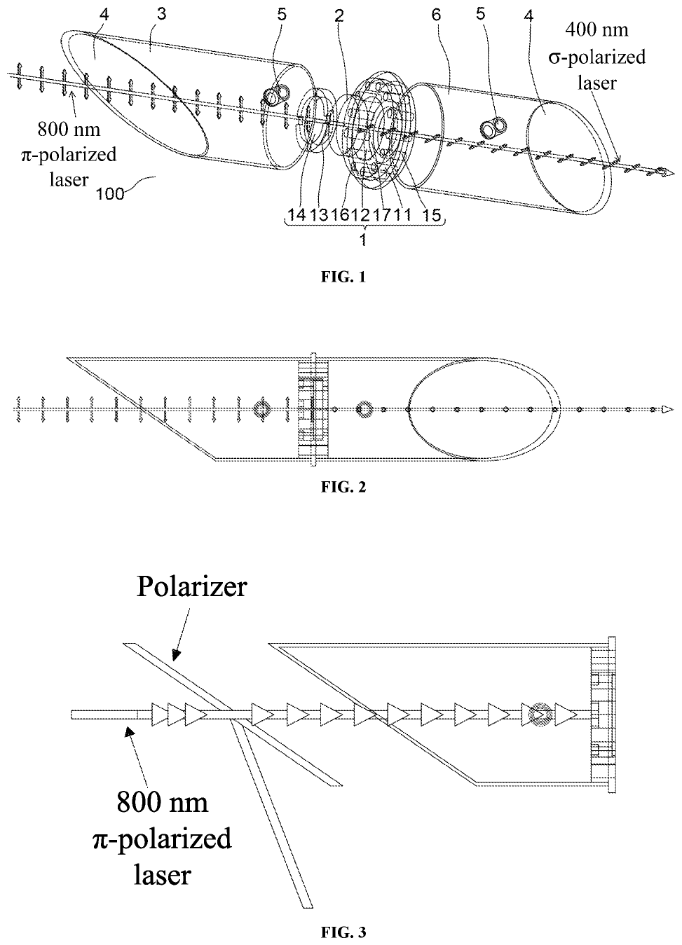

As shown in FIG. 1 to FIG. 2, this example provides a KDP frequency-doubling crystal structure 100, including a crystal fixing structure 1, a KDP crystal 2, a π polarization tube 3, and a σ polarization tube 6; where the KDP crystal 2 is fixed on the crystal fixing structure 1, and an incident plane and an emitting plane of the KDP crystal 2 are exposed on both sides of the crystal fixing structure 1, respectively; the KDP crystal 2 has a type-I phase matching angle of 43° 42′, and is configured to convert a π-polarized laser with a central wavelength of 800 nm into a σ-polarized laser with a central wavelength of 400 nm by frequency doubling; one end of the π polarization tube 3 is opened, the other end of same is closed by a Brewster angle bevel 4, and a vacuumizing port 5 is provided on a wall of the π polarization tube 3; the open end of the π polarization tube 3 is sealingly connected to one side of the crystal fixing structure 1 to seal the incident plane of the KDP crystal 2; the π polarization tube 3 is an entry end portion of a 800 nm fundamental frequency light, and its Brewster angle bevel 4 is the incident plane of the π polarization tube 3, making the fundamental frequency light with a central wavelength of 800 nm P-polarized relative to the incident plane, so as to highly transparent to the π-polarized laser with a central wavelength of 800 nm. one end of the σ polarization tube 6 is opened, and the other end of the σ polarization tube is closed by a Brewster angle bevel 4; a vacuumizing port 5 is provided on a wall of the σ polarization tube 6; the open end of the σ polarization tube 6 is sealingly connected to the other side of the crystal fixing structure 1 to seal the emitting plane of the KDP crystal 2; and the Brewster angle bevel 4 of the σ polarization tube 6 and the Brewster angle bevel 4 of the π polarization tube 3 are perpendicular to each other. The σ polarization tube 6 is an entry end portion of a 800 nm fundamental frequency light, and its Brewster angle bevel 4 is the emitting plane of the σ polarization tube 6, making the fundamental frequency light with a central wavelength of 400 nm P-polarized relative to the emitting plane, so as to highly transparent to the σ-polarized laser with a central wavelength of 400 nm. The KDP frequency-doubling crystal structure 100 involves a design method of a frequency-doubling crystal with a high damage threshold for ultra-intense and ultra-short pulses under type-I phase matching: different from the crystal coating technology, this method mainly involves a sealing design of the emitting plane and the incident plane of the KDP crystal based on theoretical loss-free characteristics of a linearly-polarized light incident at Brewster angle in the π plane. The π-polarized laser with a central wavelength of 800 nm is incident on the π polarization tube, and achieves high transparency for lasers with a central wavelength of 800 nm using the Brewster angle instead of a high-transmission dielectric film. A transmitted laser light is incident on the KDP crystal 2, the π-polarized laser with a central wavelength of 800 nm is converted into a σ-polarized laser with a central wavelength of 400 nm by frequency doubling, and is output from the σ polarization tube at Brewster angle at a high efficiency. The KDP frequency-doubling crystal structure 100 is a new crystal design solution that is proposed to address the shortcomings of current KDP crystals, such as easy deliquescence, difficulty in coating, high technical requirements, and short service life. This solution eliminates the complicated process of crystal coating and only involves simple mechanical processing to form the π polarization tube and σ polarization tube with Brewster angle bevels, thereby obtaining a high-efficiency KDP frequency-doubling crystal that is beneficial to long-term applications. This solution also provides a feasible new technical way to obtain KDP crystals with a high damage threshold under high-power frequency-doubling.

In this example, the KDP crystal 2 is preferably a cylindrical crystal, where the incident plane and the emitting plane are arranged at two axial ends of the cylindrical crystal, respectively.

In this example, based on the above design of the cylindrical KDP crystal 2, the crystal fixing structure specifically includes a hollow clamp 11 and a fixing member 13. As shown in FIG. 1, a cylindrical mounting hole 12 is opened at a center of the hollow clamp 11, and a closing ring 17 is provided at one axial end of the cylindrical mounting hole 12 to prevent the KDP crystal from falling off; the cylindrical crystal is arranged in the cylindrical mounting hole 12, one axial end of the cylindrical crystal is abutted against the closing ring 17, and an inner ring of the closing ring 17 is configured to expose one of the incident plane and the emitting plane; the fixing member 13 is connected to the other end of the cylindrical mounting hole 12 and offsets the other axial end of the cylindrical crystal to fix the cylindrical crystal in the cylindrical mounting hole 12; and a hollow-out hole 14 is provided at a center of the fixing member 13 for exposing the other one of the incident plane and the emitting plane. Preferably, in the cylindrical KDP crystal 2, the emitting plane abuts the closing ring 17, and the incident plane abuts the fixing member 13. The closing ring 7, the inner ring of the closing ring 17, and the hollow-out hole 14 each are in a circular structure, and preferably the closing ring 7, the inner ring of the closing ring 17, the hollow-out hole 14, and the cylindrical KDP crystal 2 are in coaxial arrangement.

In this example, the hollow clamp 11 is a cylindrical hollow clamp, that is, the hollow clamp 11 has a cylindrical shape, and the cylindrical mounting hole 12 is coaxially arranged with the cylindrical hollow clamp. A middle part on an outer wall of the cylindrical hollow clamp 11 protrudes radially outward to form a stepped ring 15, as shown in FIG. 2, the open end of the π polarization tube 3 is sleeved on one end of the cylindrical hollow clamp and is sealingly connected to one end face of the stepped ring 15; and the open end of the σ polarization tube 6 is sleeved on the other end of the cylindrical hollow clamp and is sealingly connected to the other end face of the stepped ring 15. Therefore, in the KDP crystal 2, the incident plane is sealed in a vacuum enclosed space enclosed by the π polarization tube 3 and the cylindrical hollow clamp, and the emitting plane is sealed in a vacuum enclosed space enclosed by the σ polarization tube 6 and the cylindrical hollow clamp. During actual use, the vacuum enclosed space enclosed by the π polarization tube 3 and the cylindrical hollow clamp as well as the vacuum enclosed space enclosed by the σ polarization tube 6 and the cylindrical hollow clamp are vacuumized through the vacuumizing port 5 to a suitable vacuum degree. This can ensure that the KDP crystal 2 is enclosed in an airtight environment, thus effectively preventing the KDP crystal 2 from deliquescence.

In this example, the open end of the π polarization tube 3 is bonded and sealed with one end face of the stepped ring 15; and the open end of the σ polarization tube 6 is bonded and sealed with the other end face of the stepped ring 15.

In this example, the vacuum enclosed space enclosed by the π polarization tube 3 and the cylindrical hollow clamp as well as the vacuum enclosed space enclosed by the σ polarization tube 6 and the cylindrical hollow clamp can be isolated from each other or connected with each other. As a preferred solution, a plurality of through holes 16 parallel to an axial direction of the hollow clamp are opened in a side wall of the cylindrical hollow clamp, as shown in FIG. 1. The plurality of through holes 16 are evenly distributed along a circumferential direction of the cylindrical hollow clamp 11, and both ends of each of the through holes 16 penetrate two axial ends of the cylindrical hollow clamp 11, thereby achieving internal communication between the π polarization tube 3 and the σ polarization tube 6. At this point, the incident plane and the emitting plane of the KDP crystal 2 are equivalent to being located in a same vacuum enclosed space.

In this example, the fixing member 13 is preferably cylindrical, and is preferably threadedly connected to the cylindrical mounting hole 12, so as to facilitate disassembly and assembly and ensure reliable connection.

Optionally, the π polarization tube 3 and the σ polarization tube 6 each are a cylindrical polarization tube, and the cylindrical KDP crystal 2, the π polarization tube 3, and the σ polarization tube 6 are arranged coaxially. During actual operations, the π polarization tube 3 and the σ polarization tube 6 each are preferably a quartz glass tube. The quartz glass has a refractive index of 1.453371 and a Brewster angle of 55.5° for a laser with a central wavelength of 800 nm; in order to satisfy the Brewster angle, the Brewster angle bevel 4 of the π polarization tube 3 needs to be set to form an included angle of 34.5° with an axis of the π polarization tube 3, namely 90°−(minus 55.5°). Correspondingly, the quartz glass has a refractive index of 1.46968 and a Brewster angle of 55.8° for a laser with a central wavelength of 400 nm; in order to satisfy the Brewster angle, the Brewster angle bevel 4 of the σ polarization tube 6 needs to be set to form an included angle of 34.2° with an axis of the σ polarization tube 6, namely 90°−(minus 55.8°).

In this example, the crystal fixing structure 1 is prepared from PTFE, that is, the fixing member 13 and the hollow clamp 11 each are prepared from the PTFE. The closing ring 17 and the stepped ring 15 are preferably integrally formed with the hollow clamp 11. During actual operation, the cylindrical crystal has a cross-sectional diameter Φ of preferably 7 mm. Correspondingly, the inner ring of the closing ring 17 and the hollow-out hole 14 each have a diameter of preferably 7 mm or slightly less than 7 mm; the cylindrical crystal has an axial length, namely a crystal thickness of preferably 2 mm. This thickness ensures that a maximum conversion efficiency can be obtained under group velocity mismatch. The cylindrical crystal has an effective aperture of 5 mm and can support CPA laser frequency-doubling with a frequency not less than 50 fs.

An installation method and a working principle of the KDP frequency-doubling crystal structure 100 will be described in detail below in conjunction with the structural design.

An installation method of the KDP frequency-doubling crystal structure 100 includes: the KDP crystal 2 was placed into the cylindrical mounting hole 12 of the hollow clamp 11, and the KDP crystal 2 was pressed with the fixing member 13; the π polarization tube 3 was placed on a left side of the hollow clamp 11, the σ polarization tube 6 is placed on a right side of the hollow clamp 11, and it was ensured that the Brewster angle bevel 4 of the π polarization tube 3 and the Brewster angle bevel 4 of the σ polarization tube 6 were perpendicular to each other; after assembly, joints between the π polarization tube 3 and the stepped ring 15 and between the σ polarization tube 6 and the stepped ring 15 were glued and sealed with a sealant; the π polarization tube 3 and the σ polarization tube 6 were vacuumized by the vacuumizing port 5 on the π polarization tube 3 or the σ polarization tube 6, or the π polarization tube 3 and the σ polarization tube 6 were vacuumized by the vacuumizing port 5 on the π polarization tube 3 and the σ polarization tube 6; after a vacuum degree reached a standard, the vacuuming was terminated, and the vacuumizing ports 5 on the π polarization tube 3 and the σ polarization tube 6 were blocked through structures such as a rubber plug, to obtain a finished KDP frequency-doubling transistor device, namely the KDP frequency-doubling crystal structure 100.

An application principle of the KDP frequency-doubling crystal structure 100 of this example will be described in detail below with reference to a specific example.

During use, the π-polarized laser with a central wavelength of 800 nm was incident on the Brewster angle bevel 4 of the π polarization tube 3, and achieved high transparency for lasers with a central wavelength of 800 nm using the Brewster angle instead of a high-transmission dielectric film. A transmitted laser light is incident on the KDP crystal 2, the π-polarized laser with a central wavelength of 800 nm was converted into a σ-polarized laser with a central wavelength of 400 nm through the KDP crystal 2 by frequency doubling, and was output from the Brewster angle bevel 4 of the σ polarization tube 6 at a high efficiency.

In optical experiments, computer numerical simulation technology has been widely used. Optical simulation experiments can describe abstract and difficult-to-understand optical concepts and laws in the form of images through the simulation interface. Professional optical design software has more powerful simulation functions and can provide more intuitive and realistic simulation effects. TracePro, as non-sequential ray tracing software based on the Monte Carlo method, is developed by Lambda Research in the United States and is commonly used in lighting systems, optical analysis, radiometric analysis, and photometric analysis. TracePro has an ability to handle complex geometric problems, defining and tracing millions of rays. This software constructs a light path system using solid objects, and simulates the interaction between light and solid surfaces by calculating behaviors such as reflection, refraction, absorption, and diffraction, thereby calculating and displaying real scenes.

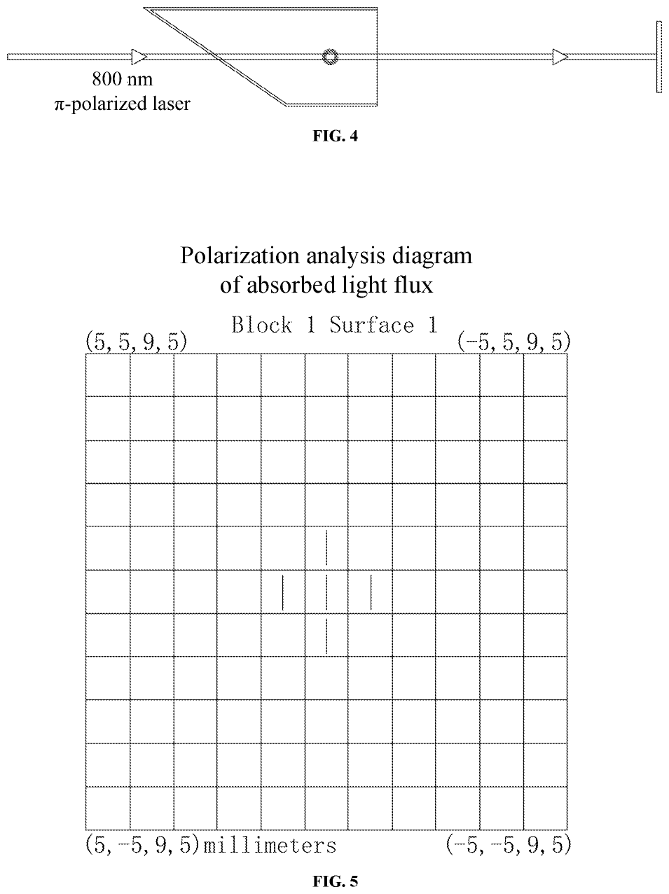

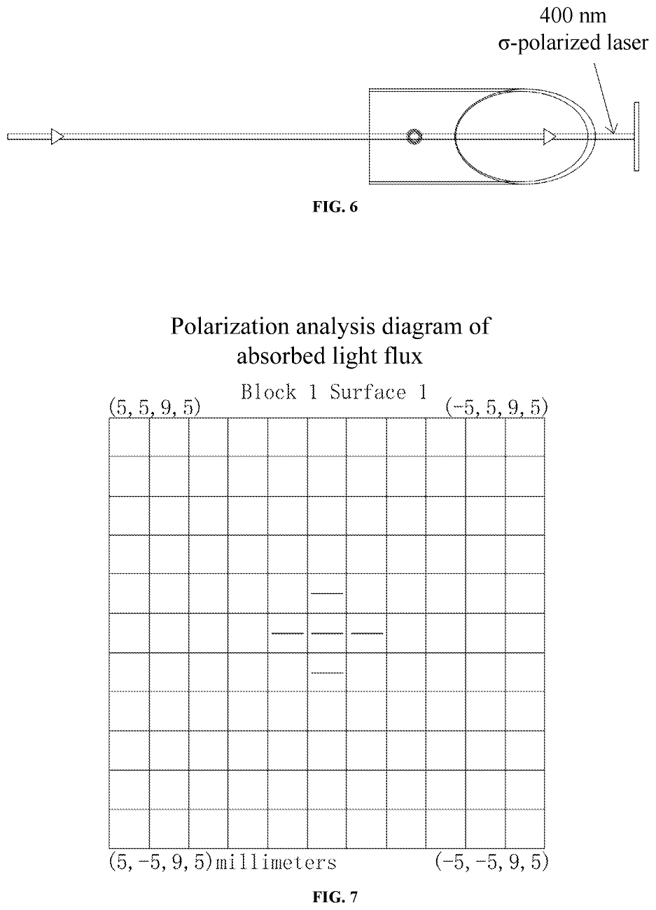

In this example, an assembly drawing of the KDP frequency-doubling crystal structure 100 was created using Solidworks mechanical drawing software, as shown in FIG. 2. The assembly drawing was imported into the TracePro software, and the materials of the π polarization tube 3 and the σ polarization tube 6 were defined as quartz glass, where the π polarization tube 3 and the σ polarization tube 6 had refractive indexes of 1.453371 and 1.46968, respectively, and showed no absorption loss. An incident light source was a parallel natural light of 800 nm, with a total number of rays of 1,000. The σ-polarized laser was reflected by a π polarization plate, thereby ensuring that the laser incident on the Brewster angle bevel 4 of the π polarization tube 3 was π-polarized laser with a central wavelength of 800 nm, as shown in FIG. 3. FIG. 4 and FIG. 6 were ray tracing diagrams of the π polarization tube 3 and σ polarization tube 6, respectively. The light polarization analysis diagrams in FIG. 5 and FIG. 7 showed σ polarization state when the laser was incident on an observation surface, where FIG. 5 and FIG. 7 were π polarization and σ polarization, respectively.

It can be seen that the design method of the KDP frequency-doubling crystal with a high damage threshold under phase matching proposed in this technical solution includes: the π-polarized laser with a central wavelength of 800 nm is introduced into the KDP frequency-doubling crystal through the π polarization tube 3; and the π-polarized laser with a central wavelength of 800 nm is converted into the σ-polarized laser with a central wavelength of 400 nm by frequency doubling, and is output from the σ polarization tube. The close end bevels of the π polarization tube and the σ polarization tube are designed into a Brewster angle. The KDP crystal is placed in a vacuum-tight tube cavity formed by the π polarization tube, the σ polarization tube, and the hollow clamp 11, which eliminates a complicated process of crystal coating and prevents the KDP crystal from deliquescence in air. The entire device involves only simple mechanical processing to obtain a high-efficiency KDP frequency-doubling crystal structure that is beneficial to long-term applications, and provides a feasible new technical way to obtain KDP crystals with a high damage threshold under high-power frequency-doubling.

It should be noted that it is obvious to those skilled in the art that the present disclosure is not limited to the details of the above exemplary embodiments, and that the present disclosure can be implemented in other specific forms without departing from the spirit or basic features of the present disclosure. Therefore, the embodiments should be regarded as exemplary and non-limiting in every respect. The scope of the present disclosure is defined by the appended claims rather than the above description, therefore, all changes falling within the meaning and scope of equivalent elements of the claims should be included in the present disclosure, and any reference numerals in the claims should not be construed as a limitation to the claims involved.

Specific examples are used herein to explain the principles and embodiments of the present disclosure. The foregoing description of the embodiments is merely intended to help understand the method of the present disclosure and its core ideas; besides, various modifications may be made by those of ordinary skill in the art to specific embodiments and the scope of application in accordance with the ideas of the present disclosure. In conclusion, the content of the description shall not be construed as limitations to the present disclosure.

What is claimed is:

1. A potassium dihydrogen phosphate (KDP) frequency-doubling crystal structure, comprising:
a crystal fixing structure;
a KDP crystal, wherein the KDP crystal is fixed on the crystal fixing structure, and an incident plane and an emitting plane of the KDP crystal are exposed outside two sides of the crystal fixing structure, respectively; and the KDP crystal is configured to convert a π-polarized laser with a central wavelength of 800 nm into a σ-polarized laser with a central wavelength of 400 nm by frequency doubling;
a π polarization tube, wherein the π polarization tube has one open end and the other end closed by a Brewster angle bevel; a vacuumizing port is provided on a wall of the π polarization tube; the open end of the π polarization tube is sealingly connected to one side of the crystal fixing structure to seal the incident plane of the KDP crystal; and the π polarization tube is configured to allow high transmission of the π-polarized laser with a central wavelength of 800 nm; and
a σ polarization tube, wherein the σ polarization tube has one open end and the other end closed by a Brewster angle bevel; a vacuumizing port is provided on a wall of the σ polarization tube; the open end of the σ polarization tube is sealingly connected to the other side of the crystal fixing structure to seal the emitting plane of the KDP crystal; and the Brewster angle bevel of the σ polarization tube and the Brewster angle bevel of the π polarization tube are perpendicular to each other, and the σ polarization tube is configured to allow high transmission of the σ-polarized laser σ with a central wavelength of 400 nm.

2. The KDP frequency-doubling crystal structure according to claim 1, wherein the KDP crystal is a cylindrical crystal, and the incident plane and the emitting plane are arranged at two axial ends of the cylindrical crystal, respectively; and the crystal fixing structure comprises:
a hollow clamp, wherein a cylindrical mounting hole is provided at a center of the hollow clamp; one axial end of the cylindrical mounting hole is provided with a closing ring to prevent the KDP crystal from falling off; the cylindrical crystal is arranged in the cylindrical mounting hole, and one axial end of the cylindrical crystal is abutted against the closing ring; and an inner ring of the closing ring is configured to expose one of the incident plane and the emitting plane; and
a fixing member, wherein the fixing member is connected to the other end of the cylindrical mounting hole and abuts against the other axial end of the cylindrical crystal to fix the cylindrical crystal inside the cylindrical mounting hole; and a hollow-out hole is provided at a center of the fixing member to expose the other one of the incident plane and the emitting plane.

3. The KDP frequency-doubling crystal structure according to claim 2, wherein the hollow clamp is a cylindrical hollow clamp, and the cylindrical mounting hole is coaxially arranged with the cylindrical hollow clamp; a middle part of the cylindrical hollow clamp protrudes radially outward to form a stepped ring; the open end of the π polarization tube is sleeved on one end of the cylindrical hollow clamp and is sealingly connected to one end face of the stepped ring; and the open end of the σ polarization tube is sleeved on the other end of the cylindrical hollow clamp and is sealingly connected to the other end face of the stepped ring.

4. The KDP frequency-doubling crystal structure according to claim 3, wherein the open end of the π polarization tube is bonded and sealed with one end face of the stepped ring; and the open end of the σ polarization tube is bonded and sealed with the other end face of the stepped ring.

5. The KDP frequency-doubling crystal structure according to claim 3, wherein a plurality of through holes parallel to an axial direction of the cylindrical hollow clamp are provided in a side wall of the cylindrical hollow clamp, the plurality of through holes are evenly distributed along a circumferential direction of the cylindrical hollow clamp, and both ends of each of the through holes penetrate two axial ends of the cylindrical hollow clamp to communicate with the π polarization tube and the σ polarization tube.

6. The KDP frequency-doubling crystal structure according to claim 2, wherein the fixing member is threadedly connected to the cylindrical mounting hole.

7. The KDP frequency-doubling crystal structure according to claim 3, wherein the fixing member is threadedly connected to the cylindrical mounting hole.

8. The KDP frequency-doubling crystal structure according to claim 4, wherein the fixing member is threadedly connected to the cylindrical mounting hole.

9. The KDP frequency-doubling crystal structure according to claim 5, wherein the fixing member is threadedly connected to the cylindrical mounting hole.

10. The KDP frequency-doubling crystal structure according to claim 2, wherein the π polarization tube and the σ polarization tube each are a cylindrical polarization tube, and the cylindrical crystal, the π polarization tube, and the σ polarization tube are arranged coaxially.

11. The KDP frequency-doubling crystal structure according to claim 3, wherein the π polarization tube and the σ polarization tube each are a cylindrical polarization tube, and the cylindrical crystal, the π polarization tube, and the σ polarization tube are arranged coaxially.

12. The KDP frequency-doubling crystal structure according to claim 4, wherein the π polarization tube and the σ polarization tube each are a cylindrical polarization tube, and the cylindrical crystal, the π polarization tube, and the σ polarization tube are arranged coaxially.

13. The KDP frequency-doubling crystal structure according to claim 5, wherein the π polarization tube and the σ polarization tube each are a cylindrical polarization tube, and the cylindrical crystal, the π polarization tube, and the σ polarization tube are arranged coaxially.

14. The KDP frequency-doubling crystal structure according to claim 10, wherein the π polarization tube and the σ polarization tube each are a quartz glass tube; and the Brewster angle bevel of the π polarization tube and an axis of the π polarization tube form an included angle of 34.5°, while the Brewster angle bevel of the σ polarization tube and an axis of the σ polarization tube form an included angle of 34.2°.

15. The KDP frequency-doubling crystal structure according to claim 10, wherein the cylindrical crystal has a type-I phase matching angle of 43° 42′, a cross-sectional diameter of 7 mm, and an axial length of 2 mm.

16. The KDP frequency-doubling crystal structure according to claim 1, wherein the crystal fixing structure is prepared from polytetrafluoroethylene (PTFE).

17. The KDP frequency-doubling crystal structure according to claim 2, wherein the crystal fixing structure is prepared from polytetrafluoroethylene (PTFE).

18. The KDP frequency-doubling crystal structure according to claim 3, wherein the crystal fixing structure is prepared from polytetrafluoroethylene (PTFE).

19. The KDP frequency-doubling crystal structure according to claim 4, wherein the crystal fixing structure is prepared from polytetrafluoroethylene (PTFE).

20. The KDP frequency-doubling crystal structure according to claim 5, wherein the crystal fixing structure is prepared from polytetrafluoroethylene (PTFE).
